(19) United States
(12) Patent Application Publication
(10) Pub. No.: US 2014/0216542 A1
(43) Pub. Date: Aug. 7, 2014

(54) SEMICONDUCTOR MATERIAL SURFACE TREATMENT WITH LASER

(71) Applicant: First Solar, Inc., Perrysburg, OH (US)

(72) Inventors: RUI SHAO, Sylvania, OH (US); Sudirukkuge Tharanga Jinasundera, San Jose, CA (US)

(73) Assignee: First Solar, Inc., Perrysburg, OH (US)

(21) Appl. No.: 14/174,691

(22) Filed: Feb. 6, 2014

Related U.S. Application Data
(60) Provisional application No. 61/761,881, filed on Feb. 7, 2013.

(51) Int. Cl. H01L 31/0236; H01L 31/18

(52) U.S. Cl. CPC H01L 31/02363; H01L 31/1864
USPC 136/256; 438/58

(57) ABSTRACT

A photovoltaic device and its method of manufacture are disclosed. The device is formed by forming a window layer over a substrate, forming an absorber layer over the window layer, and annealing the absorber layer using a laser beam to remove contaminants from the surface of the absorber layer and/or to reduce the thickness of the absorber layer.

This application claims the benefit of priority of U.S. Provisional Patent Application No. 61/761,881, filed Feb. 7, 2013, entitled: “Semiconductor Material Surface Treatment With Laser” the entirety of which is incorporated by reference herein.

### FIELD OF THE INVENTION

The disclosed embodiments relate to semiconductor devices and, more particularly, to a system and method of treating surfaces of semiconductor layers of photovoltaic devices, which include photovoltaic cells and modules containing a plurality of photovoltaic cells.

### BACKGROUND OF THE INVENTION

During fabrication of thin film photovoltaic devices, layers of semiconductor material can be applied to a substrate with one layer serving as an n-type window layer and another layer serving as a p-type absorber layer to form a p-n junction. The window layer, which is transparent, allows photons to reach the absorber layer where they are converted into electrons and holes. The movement of the electrons and holes, which is promoted by a built-in electric field at the p-n junction, produces electric current that can be output to other electrical devices through two electrodes that are electrically coupled to the window layer and absorber layer respectively.

As will be explained later, during the formation of a photovoltaic device, the absorber layer may be subjected to various processes (e.g., deposition, chlorine treatment, copper doping) that may leave unwanted contaminants on its surface. These contaminants can negatively affect efficiency of the device. It is therefore, desirable to remove contaminants on the absorber layer before depositing other layers thereon.

Additionally, very thin absorber layers (e.g., less than or equal to about 1500 nm) are desirable. Thinner absorber layers are desirable because they are more easily depleted of free carriers under bias, resulting in higher open-circuit voltage (Voc—a measure of PV device efficiency indicating the maximum voltage the device can produce). Utilization of a thin absorber layer also reduces cost.

Thin absorber layers, however, may include pinholes. Pinholes are minute defects or voids in the layers that may adversely affect operation of the photovoltaic device. Thin absorber layers often have pinholes because, the thinner the film, the higher the chance that there will be incomplete surface coverage of the underlying layer at the completion of deposition and the higher the chance that physical or chemical damage to the absorber layer during or after deposition will result in a pinhole. Pinholes can be induced a number of ways including by contaminates which hinder the accumulation of the absorber layer material at certain locations during deposition resulting in incomplete surface coverage of the underlying layer. Pinholes can also be induced by inadequate time for the deposition of materials and/or improper deposition temperatures, both of which can lead to incomplete surface coverage of the underlying layer. Further, pinholes can be induced by physical/chemical damage to the film during or after deposition.

Accordingly, it is desirable to form thin semiconductor layers (e.g., an absorber layer) using a process that reduces or eliminates pinholes while ensuring that the surfaces of the semiconductor layers are free of contaminants.

### BRIEF DESCRIPTION OF THE DRAWINGS

FIG. 1 is a schematic representation of a photovoltaic device.

FIG. 2A depicts the formation of the photovoltaic device of FIG. 1.

FIG. 2B depicts the formation of the photovoltaic device of FIG. 1 at a stage subsequent to that shown in FIG. 2A.

### DETAILED DESCRIPTION OF THE INVENTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical, or procedural changes may be made to the specific embodiments disclosed without departing from the spirit and scope of the invention.

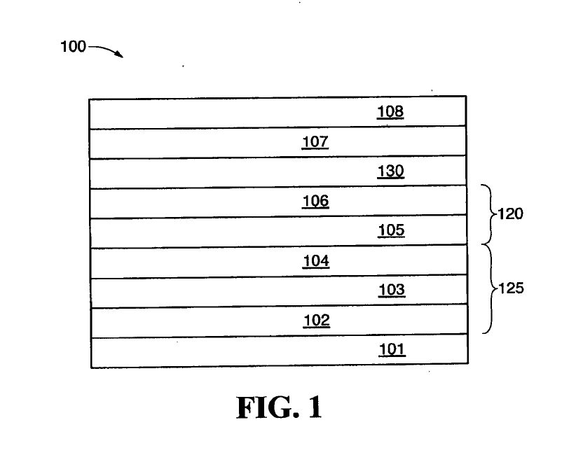

Referring to FIG. 1, an example of a photovoltaic device 100 is shown. The photovoltaic device 100 may include a substrate 101 with a transparent conductive oxide (TCO) stack 125, semiconductor device layer(s) 120 and back contact metal 107 deposited thereon. A back support 108 may be above the back contact metal 107. Substrate 101 and back support 108 are used together with an edge seal (not shown) to protect the device 100 against environmental hazards and may include any suitable material, including but not limited to glass, such as soda lime glass, low Fe glass, solar float glass or other suitable glass.

The TCO stack 125 can include a barrier layer 102, a TCO layer 103, and a buffer layer 104. The barrier layer 102 may be positioned between the substrate 101 and the TCO layer 103 to lessen diffusion of sodium or other contaminants from the substrate 101 to the semiconductor layer(s) 120. Specifically, during fabrication and while in operation, the device may be subjected to high temperatures. The high temperatures may disassociate sodium atoms from other atoms in the glass to form sodium ions. These sodium ions may become mobile and diffuse into other layers of the device. Diffusion of sodium ions in some of the layers of the device 100 (e.g., the semiconductor device layer(s) 120) may adversely affect device efficiency. To decrease the likelihood of sodium ion diffusion into those layers, the barrier layer 102 may be used. In such instances, the barrier layer 102 may include, for example, silicon dioxide, silicon aluminum oxide, tin oxide, or other suitable material or a combination thereof. Further, the barrier layer 102 may have a thickness ranging from about 10 nm to about 300 nm.

The TCO layer 103 serves as a front contact (i.e., one of the two electrodes) of the photovoltaic device 100. TCO layer 103 may include any suitable TCO material, including, for example, cadmium stannate, cadmium tin oxide, fluorine doped tin oxide, cadmium indium oxide, aluminum doped zinc oxide, or other transparent conductive oxide or combination thereof. The TCO layer 103 may have a thickness ranging from about 50 nm to about 500 nm.

The buffer layer 104 is used to improve the performance of the photovoltaic device. The buffer layer 104 may include various suitable materials, including, for example, tin oxide (e.g., tin (IV) oxide), zinc sulfer oxide, zinc tin oxide, zinc oxide or zinc magnesium oxide. The buffer layer may have a thickness ranging from about 5 nm to about 200 nm.

It should be noted that the barrier layer 102 and/or the buffer layer 104 can be omitted in some devices 100 and can be considered as optional. Semiconductor device layer(s) 120 can be deposited either on buffer layer 104, if the device 100 has one, or directly on the TCO layer 103 in the absence of a buffer layer 104. The semiconductor device layer(s) 120 can include any suitable semiconductor layer(s), including, for example a semiconductor bi-layer. The semiconductor bi-layer may include a p-type absorber layer 106 adjacent to an n-type window layer 105. As noted above, the window layer 105 allows photons to reach the p-n junction formed by the window layer 105 the absorber layer 106 where they are converted to electricity.

The semiconductor window layer 105 can be any suitable material including, but not limited to, cadmium sulfide, zinc cadmium sulfide, zinc telluride, zinc selenide, cadmium selenide, cadmium sulfur oxide, copper oxide, or a combination thereof. The semiconductor absorber layer 106 can be any suitable material including, but not limited to, cadmium telluride (CdTe), copper indium gallium (di)selenide (CIGS), or amorphous silicon. In one embodiment, the semiconductor window layer 105 is CdS having a thickness ranging from about 10 nm to about 100 nm and the semiconductor absorber layer 106 is CdTe having a thickness ranging from about 700 nm to about 10000 nm.

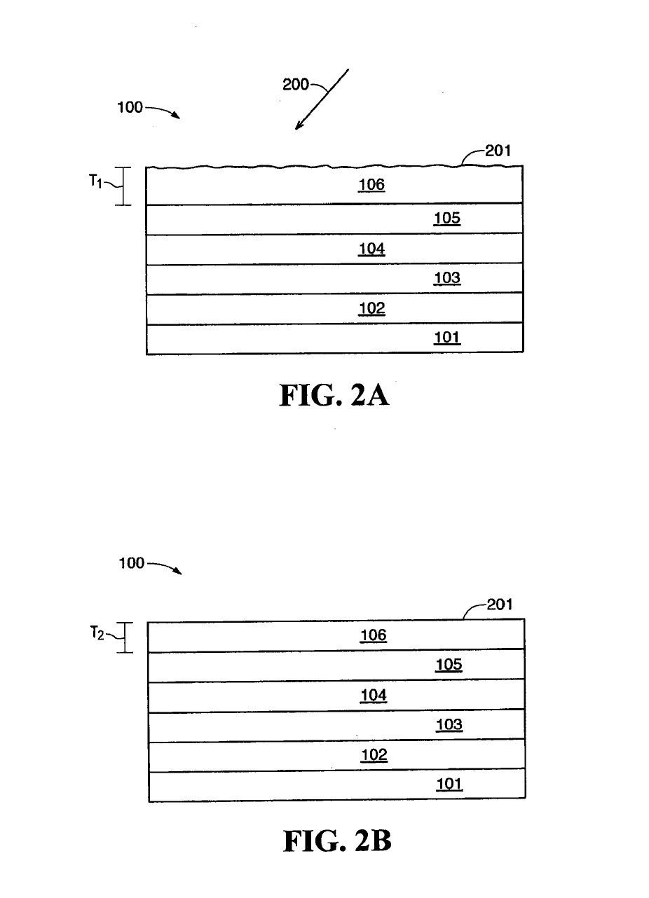

In accordance with some embodiments of the invention, after its formation, the absorber layer 106 is annealed using a laser, as described in more detail below in connection with FIGS. 2A and 2B. Annealing the absorber layer 106 with the laser may serve a plurality of purposes. For instance, contaminants on the surface of the absorber layer 106 may be burned off or ablated by the laser. This is desirable because contaminants may degrade the electric quality of the back contact 107, degrade adhesion of materials to the absorber layer 106, and prevent the diffusion of necessary dopants, such as Cu ions, into the absorber layer 106. Further, instead of initially depositing the absorber layer 106 to a thickness conforming to device specifications (e.g., less than or equal to about 1500 nm), which can lead to the formation of pinholes, the absorber layer 106 can be initially deposited with a thickness large enough to ensure a layer substantially free of pinholes. The laser can then be used to ablate the surface of the absorber layer 106 to reduce the absorber layer's thickness to desired thickness specifications. Hence, a thin absorber layer 106 substantially free of pinholes can be obtained. Lastly, the laser may smooth out any roughness on the surface of the absorber layer 106. The smoother the absorber layer 106, the thinner it may be while remaining substantially free of pinholes. Thus, in some embodiments, the absorber layer 106 can have a thickness ranging from about 1000 nm to about 1500 nm and be substantially free of pinholes.

Back contact metal 107 is located over the semiconductor layer(s) 120 and serves as the other of the two electrodes of photovoltaic device 100. The word “over” as used throughout this application does not necessarily mean “directly on” or “touching.” For instance, the back contact 107 may be located directly on the semiconductor layer(s) 120 or, alternatively, an additional layer or layers may be located between the back contact 107 and semiconductor layer(s) 120.

Optionally, additional materials, layers and/or films may be included in the device 100, such as anti-reflective coatings, and color suppression layers, among others. Anti-reflective coatings and color suppression layers aid in reducing the reflection of light to increase the amount of light transmitted into the semiconductor device layer(s) 120. The more light transmitted to the semiconductor device layer(s) 120, the more electricity that may be generated by the device 100. The more electricity generated, the more efficient the device 100.

Another optional layer that may be incorporated into the device 100 is a zinc telluride (ZnTe) layer 130. The ZnTe layer 130 may be provided between back contact metal 107 and absorber layer 106. The ZnTe layer 130 may be doped with Cu to make the layer more p-type, improving device efficiency. The Cu doped ZnTe layer 130 helps reduce recombination of electrons and holes which may otherwise occur if the back contact metal 107 is in direct contact with the absorber layer 106. It also provides an ohmic contact between the absorber layer 106 and the back contact metal 107 and helps to improve Voc and fill factor (i.e., the ratio of the actual maximum obtainable power to the product of the open circuit voltage and short circuit current). The optional ZnTe layer 130 can have a thickness of about 10 nm to about 500 nm.

Each layer in the photovoltaic device 100 may in turn include more than one layer or film. Additionally, each layer can cover all or a portion of the photovoltaic device 100 and/or all or a portion of the layer or substrate underlying the layer. For example, a “layer” can include any amount of any material that contacts all or a portion of a surface.

FIGS. 2A and 2B depict partial formations of cell 100 of FIG. 1. As shown in FIG. 2A, a substrate 101 is provided. The barrier layer 102 and TCO layer 103 are formed over the substrate 101. The buffer layer 104 is formed over the TCO layer 103. In addition, Semiconductor device layer(s) 120 can be formed on the TCO stack 125. The semiconductor device layer(s) 120, and other layers described herein, may be formed using any suitable thin-film deposition technique such as, for example, physical vapor deposition, atomic layer deposition, chemical vapor deposition, close-spaced sublimation, electrodeposition, screen printing, DC pulsed sputtering, RF sputtering, AC sputtering, chemical bath deposition, or vapor transport deposition.

The deposition techniques may leave unwanted contaminants on the surface of the absorber layer 106. For instance, depending on the deposition technique used, contaminants may include, but are not limited to, unwanted residue such as glass fines and vacuum grease from deposition equipment, CdTe dust particles, unreacted precursors, oxide layers (e.g., CdTeO₃), and unwanted copper.

Following formation of the absorber layer 106, it may be subjected to a chlorine treatment. Chlorine treatments are typically employed to facilitate recrystallization of the separate crystallites of CdTe that comprise the absorber layer 106, resulting in grain (crystalline) growth within the CdTe absorber layer 106, and to repair or passivate any chemical impurities or physical defects in the CdTe absorber layer 106 by incorporation of Cl atoms (or ions) into the absorber layer 106, particularly at the grain boundaries. This improves device efficiency because Cl repairs and passivates defects on the surface of the CdTe absorber layer 106, which increases Voc and decreases shunting.

A chlorine treatment includes applying cadmium chloride, e.g, CdCl₂, to the surface of the absorber layer 106 followed by the use of high heat to anneal the absorber layer 106. The application of the CdCl₂ to the surface of the absorber layer 106 may be through spraying a solution of CdCl₂ onto the surface of the layer 106 or by directing vapor of CdCl₂ to the surface of the layer or by any other suitable methods. After applying the CdCl₂ onto the surface of the absorber layer 106, the layer may be annealed at one or more temperatures within the range of 400° C. to 450° C. for 5 minutes to about 60 minutes or longer. The chlorine treatment, however, may leave unwanted contaminants (e.g., residue from the CdCl₂ treatment process) on the surface of the absorber layer 106. For instance, the chlorine treatment may leave several compounds, e.g., CdCl₂, CdO, CdCₓ, CdCOₓ, CdTeOₓ, TeOₓ, and CdClO, on the surface of the absorber layer 106. Oxide contaminants oxidize the surface of the CdTe absorber layer 106. For example, CdTe reacts with oxygen (O₂), producing the following: CdTe+O₂→CdTeOₓ+CdO+TeOₓ. Such contaminants may degrade the electrical contact between the CdTe absorber layer 106 surface and the back contact 107. For example, CdO, TeOₓ, CdTeO₃, and CdClO are all insulating and hinder hole transport. CdO and CdClO also attract moisture which degrades adhesion of materials or layers, such as the back contact metal 107 or the ZnTe layer 130, to the absorber layer 106.

Additionally, the absorber layer 106 may be doped with copper to make the layer more p-type, which improves device efficiency. The copper doping may be performed using any method known to those of skill in the art. For example, a solution of CuCl₂ or any other suitable wet solutions containing copper may be sprayed onto the surface of the absorber layer 106. Although copper is typically introduced after the chlorine annealing process, it may be introduced before or during the chlorine annealing process, e.g., a solution of both CuCl₂ and CdCl₂ can be introduced on the surface of the absorber layer 106. After depositing the back contact, the device may undergo heat annealing (in addition to the heat annealing performed during chlorine treatment), allowing the copper to diffuse into the CdTe absorber layer 106. The copper doping, however, may also leave unwanted contaminants, such as residue from the CuCl₂ treatment process, on the surface of the absorber layer 106. These contaminants are also insulating and hygroscopic.

As mentioned above, by increasing the initial thickness of the absorber layer 106 and conducting a laser treatment of absorber layer 106, contaminants at the surface 201 of absorber layer 106 can be burned off, the roughness of the surface 201 of absorber layer 106 can be reduced, and the absorber layer 106 can be thinner, while remaining substantially free of pinholes.

Thus, following the formation of the absorber layer 106 and any subsequent processes or treatments (e.g., CdCl₂ and/or CuCl₂ treatment) that the absorber layer 106 may be subjected to, a laser having a beam 200 as depicted in FIG. 2A is used to anneal the absorber layer 106

Laser annealing uses intense heat for very short durations. Due to this intense heat, surface contaminants can be ablated off the surface of the absorber layer 106. To laser anneal the absorber layer 106, the laser beam 200 can be scanned repeatedly across the absorber layer surface 201, at any suitable speed, e.g., about 4000 mm/s. The laser beam 200 may be a continuous wave or pulsed wave. In one embodiment, the laser beam 200 is pulsed at about 100 kHz. To effectively remove contaminants on the surface of the CdTe absorber layer 106, the annealing can be conducted in an environment of an inert gas. Any of the following inert gases may be used: argon, helium, and nitrogen. The annealing may also be conducted in an air environment.

In addition to removing surface contaminants, such as the oxides mentioned above, the laser can also ablate the upper surface 201 of the absorber layer 106 by melting and evaporation. Ablation of the absorber layer 106 surface 201 reduces the thickness T1 of the absorber layer 106. As shown in FIG. 2B, subsequent to the laser treatment of the absorber layer 106, the absorber layer 106 has a reduced thickness T2. That is, in the illustrated example, T2 (FIG. 2B) is less than T1 (FIG. 2A). The power of the laser can be adjusted to achieve the desired thickness T2 within a particular time span. That is, a higher powered laser will bring the thickness down to T2 much faster than a lowered powered laser.

Since some of the thickness of the absorber layer 106 will be ablated off, the absorber layer 106 may be initially formed with a particular thickness T1 that ensures a layer that is substantially free of pinholes. The absorber layer 106 can then be laser annealed, such that ablation occurs, to reduce the thickness down to the desired thickness T2. In one embodiment, the thickness of the absorber layer 106 is from greater than about 1500 nm to about 10000 nm prior to the laser annealing. The thickness of the absorber layer 106 is then reduced by laser ablation to be in the range of about 700 nm to about 1500 nm.

The laser treatment of the absorber layer 106 can also have a polishing effect due to the melting of the surface 201 of the absorber layer 106, resulting in a reduction in the roughness of the surface 201 of the absorber layer, as shown in FIG. 2B.

In one embodiment, the wavelength of the laser beam 200 can be about equal to or shorter than wavelengths of green light to ensure that a great majority of the energy of the laser is absorbed at the surface 201 of the CdTe absorber layer 106 rather than in the bulk of the CdTe absorber layer 106. In such cases, green laser beams having wavelengths of about 495 nm to about 570 nm, blue laser beams having wavelengths of about 450 nm to about 495 nm, and ultraviolet laser beams having wavelengths of about 200 nm to about 450 nm, can all be used for annealing the absorber layer 106. Such short wavelengths are well absorbed by the absorber layer 106 within a short distance of the surface 201 of the CdTe absorber layer 106. For example, if a green laser beam having a wavelength of about 523 nm is used, about 90% of the laser's energy is absorbed by the absorber layer 106 within about 300 nm of the surface 201 of the absorber layer 106. If a blue laser beam having a wavelength of about 452 nm is used, about 90% of the laser's energy is absorbed by the absorber layer 106 within about 150 nm of the surface 201 of the absorber layer 106. If an ultraviolet laser beam having a wavelength of about 248 nm is used, about 90% of the laser's energy is absorbed by the absorber layer 106 within about 34 nm of the surface 201 of the absorber layer 106.

Laser annealing is advantageous to standard heat annealing because the heat that it produces is concentrated on the surface of the layer that is being annealed instead of being propagated throughout the entire layer and other layers of the device 100. This is important because when a layer is exposed to heat, it may become deformed. In addition, exposing the substrate 101 to heat may also foster impurity diffusion throughout the layers of the device 100. Thus, concentrating the laser's energy at the surface 201 minimizes heat damage to the bulk of the absorber layer 106 and other layers of the device 100. Further, most of the heat from the annealed surface 201 of the absorber layer 106 dissipates quickly, causing less of a temperature increase in the bulk of the absorber layer 106 via heat conduction, also minimizing heat damage to the bulk of the CdTe absorber layer 106.

Subsequent to the laser anneal, the optional zinc telluride (ZnTe) layer 130 can be formed on the absorber layer 106, and the back contact metal 107 can then be formed on the ZnTe layer 130, if present, or formed on the absorber layer 106 directly, to serve as a back contact for photovoltaic cell 100. The back support 108 may be formed above the back contact metal 107.

A number of embodiments have been described. Nevertheless, it will be understood that various modifications may be made without departing from the spirit and scope of the invention. For example, the semiconductor layers can include a variety of other materials, as can the materials used for the other device layers discussed above. In addition, the device may contain other layers besides those discussed above. Accordingly, other embodiments are within the scope of the following claims, and the invention is not limited by the foregoing description but is only limited by the scope of the appended claims.

What is claimed as new and desired to be protected by Letters Patent of the United States is:

1. A method of manufacturing a photovoltaic device, the method comprising:
forming a window layer over a substrate;
forming an absorber layer over the window layer; and
annealing the absorber layer using a laser beam to remove contaminants from the surface of the absorber layer and/or to reduce the thickness of the absorber layer.

2. The method of claim 1, wherein the absorber layer comprises cadmium telluride.

3. The method of claim 1, wherein the window layer comprises cadmium sulfide.

4. The method of claim 1, wherein the absorber layer comprises at least one of copper indium gallium (di)selenide, amorphous silicon, polysilicon, monocrystalline silicon, gallium arsenide.

5. The method of claim 1, wherein a top surface of the absorber layer is ablated during the laser annealing.

6. The method of claim 1, wherein a roughness of a top surface of the absorber layer is reduced during the laser annealing.

7. The method of claim 1, wherein the thickness of the absorber layer is from greater than about 1500 nm to about 10000 nm prior to the laser annealing.

8. The method of claim 1, wherein the thickness of the absorber layer is from about 700 nm to about 1500 nm subsequent to the laser annealing.

9. The method of claim 1, wherein the laser beam has a wavelength of about 495 nm to about 570 nm.

10. The method of claim 1, wherein the laser beam has a wavelength of about 450 nm to about 495 nm.

11. The method of claim 1, wherein the laser beam has a wavelength of about 200 nm to about 450 nm.

12. The method of claim 1, further comprising at least one of doping the absorber layer with a dopant prior to the laser annealing, and conducting a cadmium chloride treatment after the formation of the absorber layer and prior to the laser annealing.

13. The method of claim 12, wherein the absorber layer is doped with copper prior to the laser annealing.

14. The method of claim 1, wherein the laser annealing is conducted in a gas environment comprising at least one inert gas.

15. The method of claim 1, wherein the laser beam is pulsed.

16. The method of claim 1, wherein the laser beam is continuous.

17. The method of claim 1, further comprising forming a zinc telluride layer over the absorber layer subsequent to the laser annealing.

18. The method of claim 17, further comprising forming a back contact over the zinc telluride layer.

19. The method of claim 1, further comprising forming a back contact over the absorber layer subsequent to the laser annealing.

20. A method of manufacturing a photovoltaic device, the method comprising:
forming a layer comprising cadmium sulfide over a substrate;
forming a layer comprising cadmium telluride over the cadmium sulfide layer;
conducting a cadmium chloride treatment on the cadmium telluride layer; and
annealing the cadmium telluride layer using a laser beam to remove contaminants from the surface of the cadmium telluride layer and/or to reduce the thickness of the cadmium telluride layer.

21. The method of claim 20, wherein a top surface of the cadmium telluride layer is ablated during laser annealing.

22. The method of claim 20, wherein a roughness of a top surface of the cadmium telluride layer is reduced during the laser annealing.

23. The method of claim 20, wherein the thickness of the cadmium telluride layer is from greater than about 1500 nm to about 10000 nm prior to the laser annealing.

24. The method of claim 20, wherein the thickness of the cadmium telluride layer is from about 700 nm to about 1500 nm subsequent to the laser annealing.

25. The method of claim 20, further comprising doping the cadmium telluride layer with a dopant prior to the laser annealing.

26. The method of claim 25, wherein the cadmium telluride layer is doped with copper prior to the laser annealing.

27. The method of claim 20, wherein the laser beam has a wavelength of about 495 nm to about 570 nm.

28. The method of claim 20, wherein the laser beam has a wavelength of about 450 nm to about 495 nm.

29. The method of claim 20, wherein the laser beam has a wavelength of about 200 nm to about 450 nm.

30. A photovoltaic device comprising:
a window layer over the transparent conductive layer;
an absorber layer over the window layer, the absorber layer having a laser treated surface.

31. The device of claim 30, wherein the absorber layer comprises cadmium telluride.

32. The device of claim 30, wherein the window layer comprises cadmium sulfide.

33. The device of claim 30, wherein the absorber layer comprises at least one of copper indium gallium (di)selenide, amorphous silicon, polysilicon, monocrystalline silicon, gallium arsenide.

34. The device of claim 30, wherein the absorber layer contains a dopant.

35. The device of claim 34, wherein the dopant comprises copper.

36. The device of claim 30, further comprising a zinc telluride layer over the absorber layer.

37. The device of claim 36, further comprising a back contact over the zinc telluride layer.

38. The device of claim 30, further comprising a back contact over the absorber layer.

39. The device of claim 30, wherein the absorber layer is substantially free of contaminants.

40. The device of claim 30, wherein the absorber layer has a thickness of less than about 1500 nm and is substantially free of pinholes.
